(19) United States
(12) Patent Application Publication
(10) Pub. No.: US 2008/0174957 A1
(43) Pub. Date: Jul. 24, 2008

(54) Electronic device cooling system

(76) Inventor: Jeffrey A. Lev, Cypress, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/656,833

(22) Filed: Jan. 23, 2007

(51) Int. Cl. H05K 7/20

(52) U.S. Cl. 361/694

(57) ABSTRACT

An electronic device cooling system, comprising an electronic device comprising a plurality of housing walls and at least one duct wall extending between at least one of the housing walls and a circuit board disposed within the electronic device to form a duct to enable cooling air to flow within the duct to dissipate heat from within the electronic device.

### BACKGROUND

Electronic computing devices, such as laptop computers, generate thermal energy during operation. In order to dissipate such thermal energy, electronic devices incorporate cooling fans, heat exchangers, etc. However, because of the locations of various components within the housings of the computing devices, developing airflow across the heat generating components to efficiently dissipate the generated thermal energy is difficult.

### BRIEF DESCRIPTION OF THE DRAWINGS

FIG. 1 is a diagram illustrating an electronic device in which a cooling system is employed to advantage;

FIG. 2 is a diagram illustrating a section view of the electronic device of FIG. 1 taken along the line 2-2 of FIG. 1;

FIG. 3 is a diagram illustrating another embodiment of a cooling system; and

FIG. 4 is a diagram illustrating yet another embodiment of a cooling system.

### DETAILED DESCRIPTION OF THE DRAWINGS

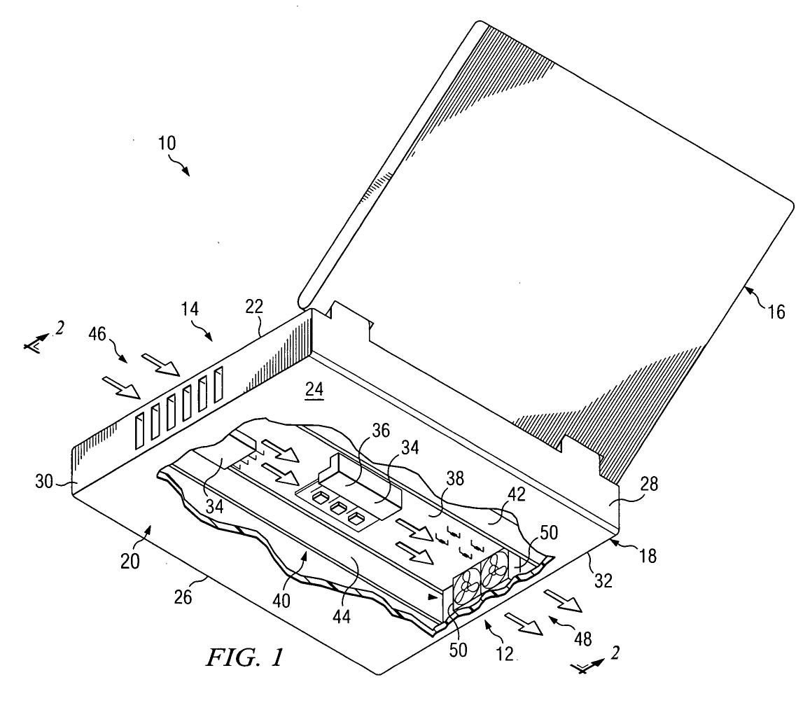

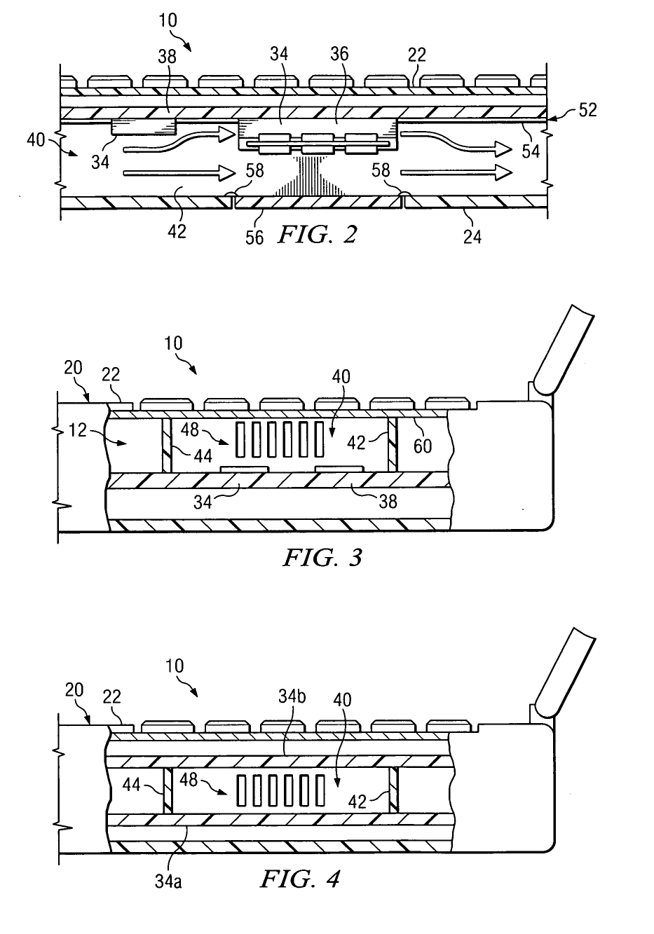

The preferred embodiments and the advantages thereof are best understood by referring to FIGS. 1-2, like numerals being used for like and corresponding parts of the various drawings.

FIG. 1 is a diagram of an electronic device 10 in which a cooling system 12 is employed to advantage. In the embodiment illustrated in FIG. 1, electronic device 10 comprises a laptop or notebook computer; however, it should be understood that electronic device 10 may comprise any type of computing device such as, but not limited to, a tablet personal computer, a personal digital assistant, a desktop computer or any other type of portable or non-portable computing device. In the embodiment illustrated in FIG. 1, electronic device 10 comprises a display member 16 rotatably coupled to a base member 18. Base member 18 comprises a housing 20 having a top wall 22, a bottom wall 24, a front wall 26, a rear wall 28 and a pair of sidewalls 30 and 32.

In the embodiment illustrated in FIG. 1, cooling system 12 is disposed within housing 20 of base member 18 and is configured to dissipate and/or otherwise remove thermal energy from an internal area of base member 18 generated by one or more computer operational components 34 disposed in housing 20. It should be understood that cooling system 12 may be otherwise disposed (e.g., within display member 16 of electronic device 10 or within both base member 18 and display member 16). Computer operational components 34 may comprise a variety of different types of operational components of electronic device 10 that generate thermal energy during operation such as, for example, a processor 36 disposed on a circuit board/motherboard 38 and/or any other type of heat generating device disposed on motherboard 38 or elsewhere within housing 20.

In the embodiment illustrated in FIG. 1, cooling system 12 comprises a duct 40 formed by bottom wall 24, motherboard 38 and a pair of duct walls 42 and 44 extending between bottom wall 24 and motherboard 38. In the embodiment illustrated in FIG. 1, duct walls 42 and 44 are both located between front wall 26 and rear wall 28 at an intermediate location within housing 20; however, it should be understood that duct walls 42 and 44 may be otherwise positioned within housing 20. Furthermore, it should be understood that duct 40 may be otherwise formed (e.g., utilizing a single ductwall 42 or 44 in combination with a wall 26, 28, 30 or 32 of housing 20). In the embodiment illustrated in FIG. 1, duct walls 42 and 44 are coupled or are otherwise positioned adjacent to bottom wall 24 and extend toward and abut at least a portion of motherboard 38 (e.g., contact motherboard 38). Duct walls 42 and 44 may be integral with bottom wall 24 (e.g., formed as a single, unitary structure) or separately attached. Housing 20 further comprises an inlet 46, an outlet 48 and at least one cooling fan 50 to enable a cooling airflow to be drawn through duct 40. In the embodiment illustrated in FIG. 1, cooling fan(s) 50 is disposed adjacent outlet 48 to pull air through duct 40; however, it should be understood that cooling air fans 50 may be otherwise disposed, such as, for example, adjacent inlet 46, at any position intermediate inlet 46 and outlet 48, or at a combination of any locations within duct 40.

In operation, cooling fan(s) 50 pulls ambient air through inlet 46 toward outlet 48. As airflow passes through duct 40, the cooling air flows across and/or adjacent to computer operational components 34, such as processor 36, to dissipate the thermal energy generated by processor 36. For example, bottom wall 24, motherboard 38 and duct walls 42 and 44 direct and/or otherwise channel cooling air at a desired velocity and/or in a desired direction across and/or adjacent to computer operational components 34 to dissipate the thermal energy. According to some embodiments, duct walls 42 and 44 are positionable within housing 20 to obtain a desired airflow velocity through duct 40. For example, it should be understood that if generally high cooling airflow velocities through duct 40 are desired, the cross sectional area of duct 40 (e.g., the boundary defined by the motherboard 38, bottom wall 24 and duct walls 42 and 44) may be reduced such as, for example, by reducing the distance between duct walls 42 and 44. Likewise, if the cooling airflow rate within duct 40 is desired to be at generally lower velocities, the cross sectional area of duct 40 may be increased such as, for example, increasing the distance between duct walls 42 and 44. Additionally or alternatively, duct 40 may have a variable cross-sectional area by varying the distance between duct walls 42 and 44 through duct 40 (e.g., by gradually increasing/decreasing the cross-sectional area through duct 40) to enable varying airflow velocities through duct 40. Accordingly, duct 40 provides an airflow path to enable cooling air to move across or adjacent to operational components 34 at desired velocities based on the size of duct 40. Furthermore, duct 40 enables cooling air to move across or adjacent to operational components 34 without being pre-heated by other heat generating operational components 34 disposed outside of duct 40 and without warming other operational components 34 inside housing 20.

According to some embodiments, duct 40 extends between housing sidewalls 30 and 32 to enable an airflow across operational components 34; however, it should be understood that duct 40 may be otherwise configured (e.g., extending from front wall 26 to rear wall 28, from sidewall 30 to front wall 26, or any other combination of walls 22, 24, 26, 28, 30 and/or 32). Duct 40 may also be configured to extend in multiple directions (e.g., from front wall 26 and branching to both sidewall 30 and rear wall 28). Furthermore, while duct 40 extends generally in a single direction (e.g., a direct straight line between inlet 46 and outlet 48), it should be understood that duct 40 may be multi-directional (e.g., turn and/or curve in any direction within housing 20); thus, it should be understood that duct walls 42 and/or 44 may be formed from a single member or may be formed by multiple members joined and/or otherwise positioned relative to each other to form duct 40. In addition, in the embodiment illustrated in FIG. 1, duct 40 comprises a constant cross-sectional area such that the space between bottom wall 24, motherboard 38, and duct walls 42 and 44 remains substantially constant along the entire length of duct 40 (e.g., the entire length between inlet 46 and outlet 48); however, it should be understood that the cross sectional area may vary in size (e.g., a gradually increasing or decreasing cross-sectional area along the length of duct 40), and may vary in geometric shape (e.g., square, rectangular, trapezoidal, etc.). In addition, it should be understood that additional walls may be used and/or otherwise positioned within housing 20 to form duct 40 (e.g., to facilitate enclosure of duct 40 where duct 40 extends beyond an edge of motherboard 38).

FIG. 2 is a diagram illustrating a section view of electronic device 10 of FIG. 1 taken along the line 2-2 of FIG. 1. In the embodiment illustrated in FIG. 2, ductwall 42 extends between bottom wall 24 and motherboard 38 and comprises a sealing member 52, such as a gasket 54 or other type sealing mechanism/material, to sealingly engage motherboard 38. Sealing member 52 is positioned on duct walls 42 and 44 to reduce and/or eliminate gaps between duct walls 42 and 44 and motherboard 38. For example, sealing member 52 is preferably configured to accommodate any surface irregularities and/or irregular shapes of motherboard 38 such as, for example, bending or warping of motherboard 38 and to accommodate the locations of any components disclosed on motherboard 38. In addition, duct walls 42 and 44 may also vary in height to accommodate variations on motherboard 38 (e.g., components disposed on motherboard 38) and/or bottom wall 24. According to some embodiments, duct 40 is positioned over an access door 56 to permit access to motherboard 38 and/or any other operational component 34 disposed within duct 40. In the embodiment illustrated in FIG. 2, access door 56 comprises a sealing member 58 disposed around a periphery of door 56 to seal the door and prevent airflow leaks therethrough. Duct walls 42 and 44 may be fabricated from any type of material such as, for example, a lightweight plastic or foam material. In the embodiment illustrated in FIGS. 1 and 2, duct walls 42 and 44 are configured to be non-load bearing walls to reduce or eliminate undesired forces on motherboard 38. However, it should be understood that Duct walls 42 and/or 44 may be configured to carry loads.

FIG. 3 is a diagram illustrating another embodiment of cooling system 12. In the embodiment illustrated in FIG. 3, cooling system 12 comprises a duct 40 formed at least in part by a keyboard base plate 60. In the embodiment illustrated in FIG. 3, duct 40 is formed by keyboard base plate 60, motherboard 38 and duct walls 42 and 44 extending between base plate 60 and motherboard 38 and keyboard base plate 60. In the embodiment illustrated in FIG. 3, duct walls 42 and 44 are coupled or are otherwise positioned adjacent to base plate 60 and extend between and abut at least a portion of motherboard 38. Duct walls 42 and 44 may be integral with base plate 60 (e.g., formed as a single, unitary structure) or may be separately attached to base plate 60 via an adhesive or any other method of attachment. It should be understood that duct walls 42 and 44 may be otherwise positioned so as to be integral or coupled to motherboard 38 and extend toward and abut base plate 60. Furthermore, it should be understood that duct walls 42 and 44 may be positioned such as, for example, duct walls 40 and/or 42 extending beyond an edge of keyboard base plate 60 and abut another portion of electronic device 10 to form duct 40 (e.g., top wall 22). It should also be understood that a sealing member (e.g., sealing member 52 of FIG. 2) may be used on one or both the ends of duct walls 42 and 44 (e.g., abutting motherboard 38 and/or keyboard base plate 60).

FIG. 4 is a diagram illustrating yet another embodiment of cooling system 12. In the embodiment illustrated in FIG. 4, cooling system 12 comprises a duct 40 formed by a pair of spaced apart first and second computer operational components 34a and 34b (e.g., two spaced apart printed circuit boards) and duct walls 42 and 44 extending between operational components 34a and 34b to enable an airflow through duct 40 so as to dissipate heat generated by operational components 34a and/or 34b. It should also be understood that a sending member (e.g., sealing member 52 of FIG. 2) may be used on one or both the ends of duct walls 42 and 44 (e.g., abutting motherboard operational components 34a and/or 34b).

Thus, embodiments of system 12 provide a duct 40 extending within electronic device 10 to enable a cooling airflow to increase the heat dissipation rate from operational components 34 within device 10. Furthermore, embodiments of system 12 provide a duct 40 utilizing existing portions of the electronic device 10 such as, for example, motherboard 38 and bottom wall 24, keyboard base plate 60 and motherboard 38, or between spaced apart operational components 34a and 34b, to form duct 40. In addition, embodiments of system 12 also provide a sealing member 52 disposed on duct walls 42 and/or 44 to accommodate surface irregularities of motherboard 38 or other components forming duct 40 to prevent leaks between duct walls 42 and 44 and motherboard 38.

What is claimed is:

1. An electronic device cooling system, comprising
an electronic device comprising a plurality of housing walls; and
at least one duct wall extending between at least one of the housing walls and a circuit board disposed within the electronic device to form a duct to enable cooling air to flow within the duct to dissipate heat from within the electronic device.

2. The system of claim 1, wherein the at least one duct wall abuts the circuit board.

3. The system of claim 1, wherein the at least one duct wall extends between the circuit board and at least a portion of a keyboard base plate of the electronic device.

4. The system of claim 1, wherein the at least one duct wall comprises a sealing member for sealing engagement with the circuit board.

5. The system of claim 1, wherein the duct extends at least partially over an access door disposed on at least one of the housing walls.

6. The system of claim 1, wherein the duct comprises a constant cross-sectional area.

7. The system of claim 1, wherein the duct is unidirectional.

8. A method of manufacturing an electronic device cooling system, comprising
providing an electronic device comprising a plurality of housing walls; and
providing at least one duct wall extending between at least one of the housing walls and a circuit board disposed in the electronic device to form a duct to enable cooling air to flow within the duct to dissipate heat from within the electronic device.

9. The method of claim 8, further comprising extending the at least one duct wall to abut the circuit board.

10. The method of claim 8, further comprising coupling a sealing member to the at least one duct wall to enable sealing engagement with the circuit board.

11. The method of claim 8, further comprising forming the duct to extend at least partially over an access door disposed on at least one of the housing walls.

12. The method of claim 8, further comprising positioning the at least one duct wall between the circuit board and at least a portion of a keyboard base plate of the electronic device.

13. The method of claim 8, further comprising forming the duct having a constant cross-sectional area.

14. The method of claim 8, further comprising forming the duct being unidirectional.

15. An electronic device cooling system, comprising:
a means for housing a circuit board means, the housing means comprising a plurality of wall means; and
at least one duct wall means extending between at least one of the housing wall means and the circuit board means to form a duct means to direct cooling air flow to dissipate heat from the housing means.

16. The system of claim 15, wherein the duct wall means extends from at least one of the housing wall means walls to abut the circuit board means.

17. The system of claim 15, wherein the duct wall comprise a means to sealingly engage the circuit board means.

18. An electronic device cooling system, comprising
a cooling air duct disposed within a housing of an electronic device, the cooling air duct formed by a first circuit board, a second circuit board and at least one duct wall extending between the first and second circuit boards.

19. The system of claim 18, wherein the at least one duct wall comprises a sealing member for sealing engagement with at least one at the first and second circuit boards.

20. The system of claim 18, wherein the cooling air duct is unidirectional.
